(19) United States
(12) Patent Application Publication
(10) Pub. No.: US 2023/0041075 A1
(43) Pub. Date: Feb. 9, 2023

(54) OPTICAL PROXIMITY CORRECTION METHOD USING CHIEF RAY ANGLE AND PHOTOLITHOGRAPHY METHOD INCLUDING THE SAME

(71) Applicant: Samsung Electronics Co., Ltd., Suwon-si (KR)

(72) Inventors: Jeong-Lim KIM, Seoul (KR); Jae Myoung LEE, Hwaseong-si (KR); Sung Gon JUNG, Seongnam-si (KR)

(21) Appl. No.: 17/671,021

(22) Filed: Feb. 14, 2022

(30) Foreign Application Priority Data
Aug. 4, 2021 (KR) 10-2021-0102286

(51) Int. Cl. G03F 1/36

(52) U.S. Cl. CPC G03F 1/36

(57) ABSTRACT

An optical proximity correction method includes designing a mask design. The designing of the mask design includes setting a reference point of the mask design, calculating a plurality of chief ray angles of a plurality of points of interest on the mask design, respectively, each of the plurality of points of interest having a corresponding distance from the reference point, finding, among the plurality of points of interest, a first point of interest having a maximum chief ray angle among the plurality of chief ray angles, a distance of the first point of interest from the reference point being set as a deteriorated distance, and compensating for distortion of an image to be transferred from a pattern located at the deteriorated distance from the reference point of the mask design.

This application claims the benefit of Korean Pat. Application No. 10-2021-0102286, filed on Aug. 4, 2021, in the Korean Intellectual Property Office, the disclosure of which is incorporated herein in its entirety by reference.

### BACKGROUND

### 1. Technical Field

The present disclosure relates to an optical proximity correction method using a chief ray angle, and more particularly, to a photolithography method including an optical proximity correction method using a chief ray angle.

### 2. Description of the Related Art

When an integrated circuit is designed, the layout of the circuit is manufactured to form a desired circuit on a semiconductor substrate. The layout may be transferred to a wafer surface through a photomask. As integrated circuit design becomes complicated due to high integration of semiconductor devices, it is very important to accurately implement a pattern layout according to an initially intended design on a semiconductor manufacturing mask for a photolithography process.

As the wavelength of a light source used in exposure equipment becomes close to the feature size of a semiconductor device, pattern distortion may occur due to light diffraction, interference, and the like. Accordingly, an optical proximity effect in which an image of a shape different from the original shape is formed on a wafer or the shape of a pattern is distorted by the effect of an adjacent pattern may occur. In order to prevent problems such as changes in dimensions due to the optical proximity effect, an optical proximity correction process may be performed. In the optical proximity correction process, changes in dimensions during pattern transfer may be predicted in advance, and a designed pattern may be modified in advance so that a pattern shape according to a desired layout can be obtained after the pattern transfer.

In order to improve the reliability of a mask manufactured through optical proximity correction, a mask design may be designed using a chief ray angle during an optical proximity correction process.

### SUMMARY

Aspects of the present disclosure provide an optical proximity correction method using a chief ray angle having improved critical dimension uniformity.

Aspects of the present disclosure also provide a method of manufacturing a semiconductor package having improved critical dimension uniformity.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present invention, an optical proximity correction method includes designing a mask design. The designing of the mask design includes setting a reference point of the mask design, calculating a plurality of chief ray angles of a plurality of points of interest on the mask design, respectively, each of the plurality of points of interest having a corresponding distance from the reference point, finding, among the plurality of points of interest, a first point of interest having a maximum chief ray angle among the plurality of chief ray angles, a distance of the first point of interest from the reference point being set as a deteriorated distance, and compensating for distortion of an image to be transferred from a pattern located at the deteriorated distance from the reference point of the mask design.

According to an embodiment of the present invention, an optical proximity correction method includes designing a mask design. The designing of the mask design includes setting a reference point of the mask design, setting a plurality of zones on the mask design, the plurality of zones being concentric with reference to the reference point, calculating a plurality of chief ray angles of a plurality of points of interest on the mask design, respectively, each of the plurality of points of interest having a corresponding distance from the reference point, respectively, finding, among the plurality of points of interest, a first point of interest having a maximum chief ray angle among the plurality of chief ray angles, setting, among the plurality of zones, a first zone where the first point of interest having the maximum chief ray angle is located as a deteriorated zone, and compensating for distortion of an image to be transferred from a pattern located in the deteriorated zone.

According to an embodiment of the present invention, a photolithography method uses a mask design on which an optical proximity correction method has been performed. The optical proximity correction method includes designing the mask design. The designing of the mask design includes setting a reference point of the mask design, calculating a plurality of chief ray angles of a plurality of points of interest on the mask design, respectively, each of the plurality of points of interest having a corresponding distance from the reference point, finding, among the plurality of points of interest, a first point of interest having a maximum chief ray angle among the plurality of chief ray angles, a distance of the first point of interest from the reference point being set as a deteriorated distance, and compensating for distortion of an image to be transferred from a pattern placed at the deteriorated distance from the reference point of the mask design.

### BRIEF DESCRIPTION OF THE DRAWINGS

These and/or other aspects will become apparent and more readily appreciated from the following description of the embodiments, taken in conjunction with the accompanying drawings in which:

FIG. 1, and FIGS. 1A to 1C are an exemplary diagram for explaining a chief ray angle.

FIG. 2 is an exemplary diagram for explaining an optical proximity correction method according to embodiments.

FIG. 3 is an after development inspection (ADI) scatter graph for checking reliability after a photolithography process is performed due to a deteriorated zone.

FIG. 4 is an exemplary diagram for explaining an optical proximity correction method using a chief ray angle according to embodiments.

FIG. 5 is an exemplary graph illustrating the change in chief ray angle with respect to the distance from the reference point R of FIG. 4.

FIG. 6 is an ADI scatter graph for checking reliability after a photolithography process is performed on a mask design whose deteriorated zone has been compensated through an optical proximity correction method according to embodiments.

FIG. 7 is an exemplary diagram for explaining an optical proximity correction method according to embodiments.

FIG. 8 is an exemplary flowchart illustrating an optical proximity correction method according to embodiments.

FIG. 9 is an exemplary diagram for explaining an optical proximity correction method according to embodiments.

FIG. 10 is an exemplary graph illustrating the change in chief ray angle with respect to the zone defined from the reference point R of FIG. 9.

FIG. 11 is an exemplary flowchart illustrating an optical proximity correction method according to embodiments.

### DETAILED DESCRIPTION

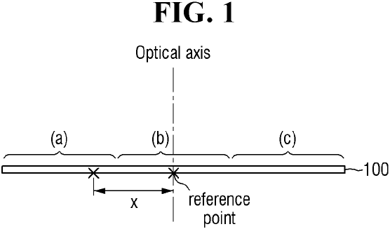

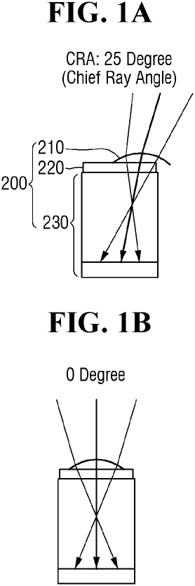

FIG. 1, and FIGS. 1-A to 1-C are diagrams for explaining a chief ray angle. FIG. 1 shows an image sensor 100 including a plurality of pixels. FIG. 1-Ashows a pixel located at a region (a) of the image sensor 100, FIG. 1-B shows a pixel located at a region (b) of the image sensor 100, and FIG. 1-C shows a pixel located at a region (c) of the image sensor 100.

Referring to FIG. 1, in order to improve characteristics of a complementary metal-oxide-semiconductor (CMOS) image sensor (CIS), a camera module and/or a prism module may be applied to an image sensor 100. A case where the prism module is applied to the CIS will be described below.

Here, the prism module may serve to align optical axes of various optical systems such as at least one microlens of the image sensor 100 and at least one lens optically coupled to the image sensor 100. For example, optical axis alignment may prevent a large aberration due to various optical systems from occurring, thereby avoiding a blurred image at an edge region of the image sensor 100.

Therefore, it may be necessary to calculate the chief ray angle. The chief ray angle will be described in detail below.

The image sensor 100 includes a plurality of pixels 200. Each of the pixels 200 may include a microlens array 210, an RGB filter 220, and an imaging device 230.

Here, values of angles of chief rays incident on the pixels 200 in a center region (b) and edge regions (a) and (c) of the image sensor 100 may differ by about 25 degrees. This difference between the values of the chief ray angles is merely an example and is not limited to 25 degrees as shown in the current drawing. In some embodiments, a chief ray angle of each pixel is an angle between a light ray passing a center of a microlens and an optical axis of the microlens. The light ray passing the center of the microlens in each pixel is represented by a thick line. The optical axis of the microlens in each pixel is an imaginary line perpendicularly passing the center of the microlens. In some embodiments, a center of the image sensor may be set to as the reference point, and each pixel has a corresponding distance of x which is a distance between the center of the image sensor and the pixel.

A chief ray angle may be calculated through Equation 1:

$$\text{c6x\textasciicircum} 6 \text{+c5x\textasciicircum} 5 \text{+c4x\textasciicircum} 4 \text{+c3x\textasciicircum} 3 \text{+c2x\textasciicircum} 2 \text{+c1x}$$

In Equation 1, x represents a distance from an arbitrary reference point in the image sensor 100, c6 is -0.2995, c5 is 3.083, c4 is -10.67, c3 is 13.44, c2 is -8.388, and c1 is 25.12. For example, the distance of x may be a distance between the arbitrary reference point and a pixel of the image sensor. Each pixel has a corresponding distance of x with reference to the arbitrary reference point of the image sensor 100. An equation used to calculate the chief ray angle is not limited to Equation 1, and the chief ray angle may be calculated using various equations.

In order to solve the difference between the values of the chief ray angles described above, a chief ray angle shrinkage may be calculated through Equation 2:

$$2.930 * tan \left(arcsin \left(sin \left(\text{CRA} * \text{pi} / 180\right) / 1.57755\right)\right)$$

In Equation 2, CRA represents a chief ray angle, and pi is the ratio of the circumference of a circle to its diameter. In some embodiments, the circle may have the arbitrary reference point as a center of the circle. An equation used to calculate the chief ray angle shrinkage is not limited to Equation 2, and the chief ray angle shrinkage may be calculated using various equations.

In some embodiment, the position of the microlens 210 may be set to intentionally deviate from the axis of the imaging device 230 by using the value of the chief ray angle shrinkage calculated through Equation 2. For example, at the center region (b), a microlens array 210 may be aligned with an imaging device 230. However, at the edge region (a), a microlens array 210 may be shifted to the right with respect to an imaging device 230 (FIG. 1-A), and at the edge region (c), a microlens array 210 may be shifted to the left with respect to an imaging device 230 (FIG. 1-C). At the center region (b), a microlens array 210 may be aligned to the center of the image device 230 (FIG. 1-B). Hereinafter, the concept of the chief ray angle in the image sensor 100 will be applied to manufacturing a mask to be used in a photolithography. A pixel on the image sensor 100 may correspond to a point of interest on a mask design, which will be described.

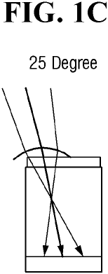

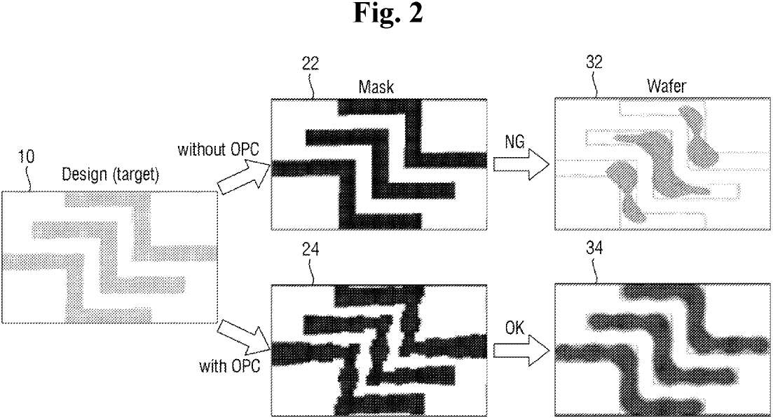

FIG. 2 is an exemplary diagram for explaining an optical proximity correction method according to embodiments.

Referring to FIG. 2, optical proximity correction (OPC) will be described by way of example. A lithography process is a process of applying a photoresist layer on a wafer (or substrate) and then exposing and developing the photoresist layer. The lithography process may be performed before an etching process or ion implantation process performed using a mask.

As semiconductor devices become highly integrated, the size and pitch of patterns constituting circuits are gradually reduced. Therefore, lithography process technology used during a process of processing a semiconductor device may refine the design of a semiconductor manufacturing mask by appropriately adjusting the amount of light emitted through the mask.

However, as the degree of integration of semiconductor devices increases, the size of a pattern formed on a mask becomes closer to the wavelength of a light source. As a result, the effect of light diffraction and interference increases in the lithography technology, and the pattern formed on the mask may be transferred on a wafer (or substrate) in a distorted manner.

For example, it is assumed that a target design pattern 10 to be formed on a wafer (or substrate) is formed on a mask 22 as it is without any compensation using OPC, for example. If a lithography process is performed using the mask 22, a pattern severely distorted from the originally intended pattern may be formed on a wafer 32.

In particular, an optical proximity effect may occur on corners of the target design pattern 10. The image of the target design pattern 10 (i.e., the actual patterns on the wafer 32) may have a distorted round shape, corresponding to corners of the target design pattern 10, on the wafer 32.

As a technology for removing the above optical proximity effect, optical proximity correction in which pattern distortion is corrected by intentionally modifying the shape of the target design pattern 10 may be used. The optical proximity correction may include adding a corner serif pattern or a hammer pattern to a line end of the target design pattern 10. The target design pattern 10 with the corner serif pattern or the hammer pattern (i.e., the resultant pattern of the OPC) may be transferred on a mask 24.

When the resultant pattern of the mask 24 on which the optical proximity correction has been performed is transferred onto a wafer (or substrate), a shape close to the shape of the originally intended pattern may be formed on the wafer 34.

The optical proximity correction described in FIG. 2 is one of various kinds of optical proximity correction. In some embodiments, in addition to the example of FIG. 2, an insertion of scattering bar method may be used as the optical proximity correction. The insertion of scattering bar method adds a plurality of sub-resolution scattering bars to the periphery of the target design pattern 10 to minimize a change in critical dimension of the pattern according to pattern density.

However, in order to increase the accuracy of the optical proximity correction, a deteriorated zone in the target design pattern 10 may be found using a chief ray angle and then may be intensively compensated. In some embodiments, designing a mask design for performing the optical proximity correction may be included in the optical proximity correction method.

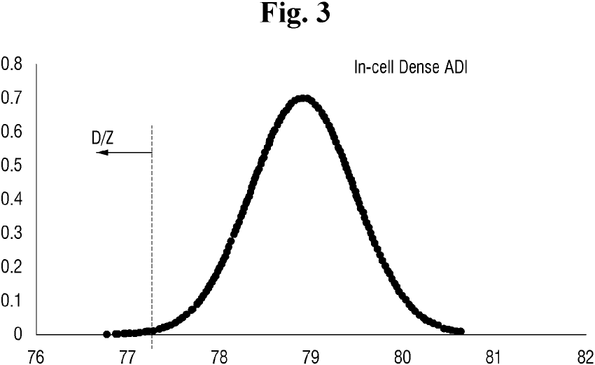

A deteriorated zone formed in the target design pattern 10 will now be described with reference to FIG. 3.

FIG. 3 is an after development inspection (ADI) scatter graph for checking reliability after a photolithography process is performed due to a deteriorated zone.

Referring to FIGS. 2 and 3, the distribution of pattern critical dimensions through ADI is illustrated. Here, it can be seen from pattern critical dimensions existing in a deteriorated zone D/Z that reliability after a photolithography process is performed on the target design pattern 10 has deteriorated.

Finding of the deteriorated zone D/Z in the target design pattern 10 prior to a photolithography process may be desirable. According to the present invention, using a chief ray angle, the deteriorated zone D/Z in the targe design pattern 10 may be found prior to a photolithography process, and then the deteriorated zone S/Z is to be intensively compensated using OPC. A method of finding the deteriorated zone D/Z in the target design pattern 10 by using a chief ray angle will be described below.

FIG. 4 is an exemplary diagram for explaining an optical proximity correction method using a chief ray angle according to embodiments.

Referring to FIG. 4, a reference point R is set to find a deteriorated zone in a mask design (e.g., a target design pattern 10).

The reference point R may be located at a point where an imaginary center line IL1 of a vertical width of the mask design 10 meets an imaginary center line IL2 of a horizontal width.

Although the reference point R is illustrated as being located at the center of the mask design in the current drawing, the position of the reference point R is not limited to the center of the mask design.

For example, the position of the reference point R may be set at any position in the mask design.

Next, a chief ray angle at each of a plurality of points of interest which are distant at distances x1, x2, and x3 through xn (where n is a natural number) from the reference point R of the mask design 10 may be calculated. Each point of interest on the mask design may have a corresponding chief ray angle according to a distance from the reference point R.

The chief ray angle may be calculated through Equation 1 described above with reference to FIG. 1. However, an equation used to calculate the chief ray angle is not limited to Equation 1.

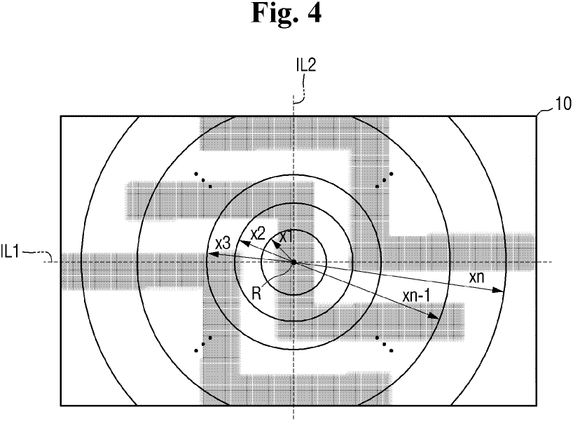

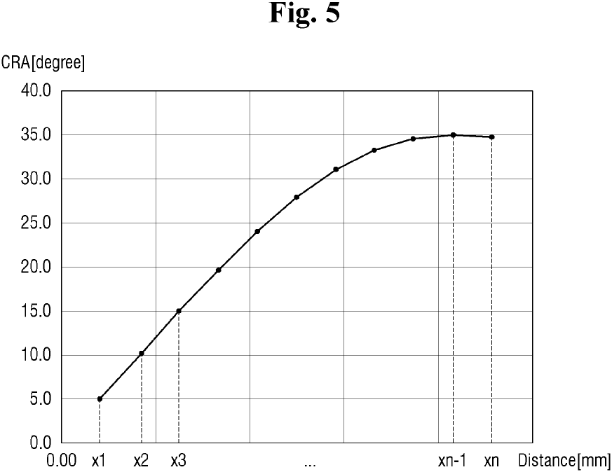

The chief ray angle calculated at each of the plurality of points of interest which have the distances x1, x2, and x3 through xn (where n is a natural number) from the reference point R of the mask design may be represented on a graph as illustrated in FIG. 5.

FIG. 5 is an exemplary graph illustrating the change in chief ray angle with respect to the distance from the reference point R of FIG. 4.

Referring to FIGS. 4 and 5, the horizontal axis represents a plurality of distances x1, x2, and x3 through xn (where n is a natural number) of a plurality of points of interest, respectively, from the reference point R of the mask design in mm. The vertical axis represents a chief ray angle calculated at each of the plurality of points of interest that have the distances x1, x2, and x3 through xn (where n is a natural number), respectively, from the reference point R of the mask design in degrees.

In an optical proximity correction method according to embodiments, a point of interest having a maximum chief ray angle is in a deteriorated zone of the mask design.

For the sake of descriptions, it is assumed that a chief ray angle at a point of interest having the distance xn-1 from the reference point R of the mask design 10 has a maximum value of 35.

In this case, it may be determined that a pattern at the distance xn-1 from the reference point R of the mask design 10 has deteriorated. The distance xn-1 from the reference point R of the mask design 10 may be defined as a deteriorated distance.

Then, a deterioration compensation process may be performed on the point of interest having the distance xn-1 defined as the deteriorated distance from the reference point R of the mask design 10. The deterioration compensation process may be, for example, optical proximity correction. In some embodiments, the deterioration compensation process may be, for example, a compensation process of adding a corner serif pattern or a hammer pattern to a line end of the pattern at the deteriorated distance.

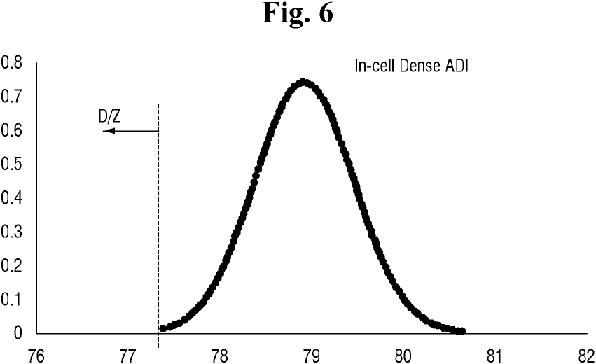

As a result of finding the deteriorated distance of the mask design 10 and performing the deterioration compensation process as described above, the distribution of pattern critical dimensions through ADI may be shown as in FIG. 6.

FIG. 6 is an ADI scatter graph for checking reliability after a photolithography process is performed on a mask design whose deteriorated zone has been compensated through an optical proximity correction method according to embodiments.

Referring to FIG. 6, the distribution of pattern critical dimensions through ADI is shown. Here, it can be seen that pattern critical dimensions no longer exist in the deteriorated zone D/Z. Reliability after a photolithography process is performed on the target design pattern 10 is improved by finding a deteriorated distance or a deteriorated zone in the mask design and then performing deterioration compensation using OPC.

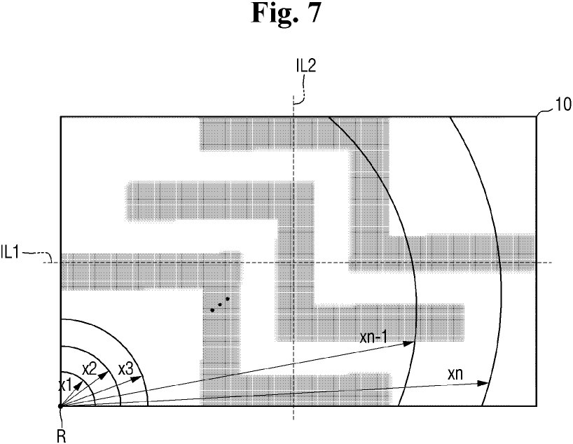

FIG. 7 is an exemplary diagram for explaining an optical proximity correction method according to embodiments.

Referring to FIG. 7, a reference point R is set to find a deteriorated zone in a mask design (e.g., a target design pattern 10). In the current drawing, the reference point R is located at an edge of the mask design. However, the position of the reference point R is not limited to an edge of the mask design.

For example, the position of the reference point R may be set at any position of the mask design.

Next, a chief ray angle at each of a plurality of points of interest which have distances x1, x2, and x3 through xn (where n is a natural number), respectively, from the reference point R of the mask design may be calculated.

The chief ray angle may be calculated using Equation 1 described above with reference to FIG. 1. However, an equation used to calculate the chief ray angle is not limited to Equation 1.

The chief ray angle calculated at each of the plurality of points of interest that have the distances x1, x2, and x3 through xn (where n is a natural number), respectively, from the reference point R of the mask design may be represented on a graph as illustrated in FIG. 5.

Reliability after a photolithography process is performed on the target design pattern 10 is improved by finding a deteriorated distance or a deteriorated zone in the mask design and then performing deterioration compensation.

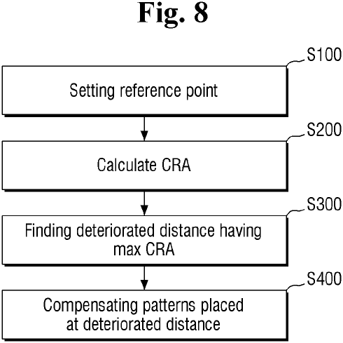

FIG. 8 is an exemplary flowchart illustrating an optical proximity correction method according to embodiments. For reference, any redundant description will be omitted for the sake of simplicity of description.

Referring to FIGS. 4 and 8, in the optical proximity correction method according to the embodiments, a reference point R of a mask design 10 is set first (operation S100).

Then, a chief ray angle at each of a plurality of points of interest that have a plurality of distances x1, x2, and x3 through xn (where n is a natural number), respectively, from the reference point R of the mask design 10 is calculated (operation S200).

Then, a point of interest having a maximum chief ray angle is found in the mask design 10 (operation S300), and a distance of the point of interest having the maximum chief ray angle is set as a deteriorated distance.

Then, a deterioration compensation process is performed on patterns placed at the deteriorated distance. In some embodiments, the deteriorated compensation process may include performing OPC on the patterns placed at the deteriorated distance. In some embodiments, the deteriorated compensation process may include adjusting a critical dimension of the patterns in the deteriorated distance.

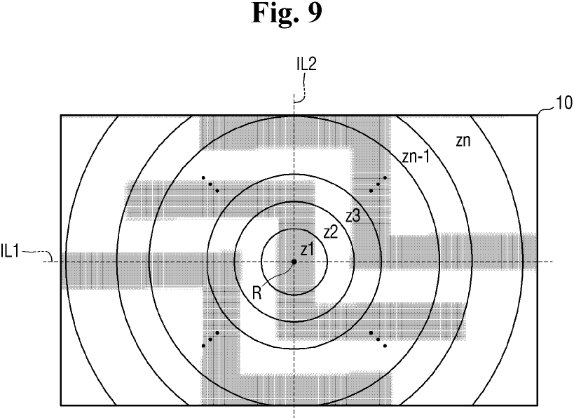

FIG. 9 is an exemplary diagram for explaining an optical proximity correction method according to embodiments.

Referring to FIG. 9, in the optical proximity correction method according to the embodiments, a mask design 10 may be divided into a plurality of zones, each being defined as a zone between two different adjacent distances from an arbitrary reference point R.

For example, the mask design 10 may be divided into a plurality of zones z1 through zn.

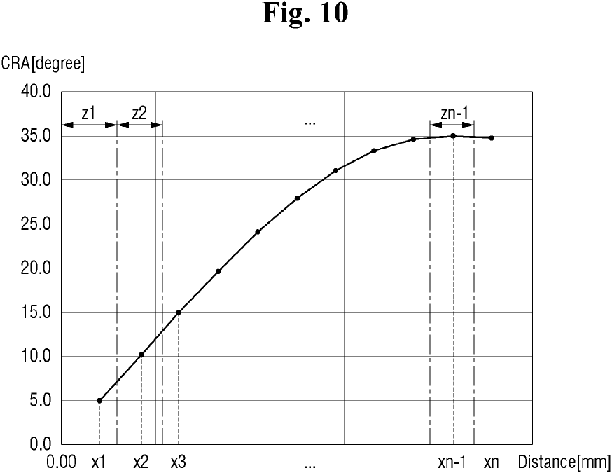

Here, a chief ray angle at each of a plurality of distances from the reference point R in the mask design 10 may be calculated. This will now be described with reference to FIG. 10.

FIG. 10 is an exemplary graph illustrating the change in chief ray angle with respect to the zone defined from the reference point R of FIG. 9.

Referring to FIGS. 9 and 10, the horizontal axis represents a plurality of distances x1, x2, and x3 through xn (where n is a natural number) of a plurality of points of interest, respectively, from the reference point R of the mask design in mm. The vertical axis represents a chief ray angle calculated at each of the distances x1, x2, and x3 through xn (where n is a natural number) from the reference point R of the mask design in degrees.

In an optical proximity correction method according to embodiments, a point of interest with a deteriorated distance having a maximum chief ray angle is in a deteriorated zone of the mask design.

For the sake of descriptions, it is assumed that a chief ray angle of a point of interest having the distance xn-1 from the reference point R of the mask design 10 has a maximum value of 35.

In this case, it may be determined that a pattern at the (n-1) distance xn-1 from the reference point R of the mask design 10 has deteriorated. The distance xn-1 from the reference point R of the mask design 10 may be defined as a deteriorated distance.

A zone zn-1 including the deteriorated distance xn-1 may be defined as a deteriorated zone.

Then, a deterioration compensation process may be performed on patterns disposed in the zone (zn-1) defined as the deteriorated zone. The deterioration compensation process may be, for example, optical proximity correction. For example, the deterioration compensation process may be, for example, a compensation process of adding a corner serif pattern or a hammer pattern to a line end of each pattern in the deteriorated zone.

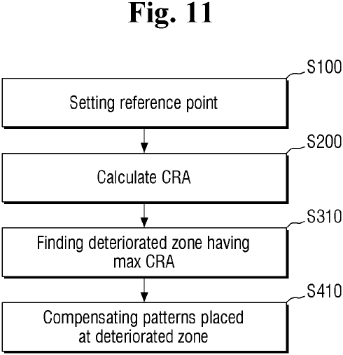

FIG. 11 is an exemplary flowchart illustrating an optical proximity correction method according to embodiments.

Referring to FIGS. 9 and 11, in the optical proximity correction method according to the embodiments, a reference point R of a mask design 10 is set first (operation S100).

Then, a chief ray angle at each of a plurality of points of interest that have a plurality of distances x1, x2, and x3 through xn (where n is a natural number), respectively, from the reference point R of the mask design 10 is calculated (operation S200).

Then, a deteriorated zone including a point of interest with a deteriorated distance having a maximum chief ray angle is found in the mask design 10 (operation S310).

Then, a deterioration compensation process is performed on patterns placed in the deteriorated zone (operation S410). In some embodiments, the deteriorated compensation process may include performing OPC on all patterns placed in the deteriorated zone. In some embodiments, the deteriorated compensation process may include adjusting a critical dimension of the patterns in the deteriorated zone.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. An optical proximity correction method comprising:
designing a mask design,
wherein the designing of the mask design comprises:
setting a reference point of the mask design;
calculating a plurality of chief ray angles of a plurality of points of interest on the mask design, respectively, wherein each of the plurality of points of interest has a corresponding distance from the reference point;
finding, among the plurality of points of interest, a first point of interest having a maximum chief ray angle among the plurality of chief ray angles, wherein a distance of the first point of interest from the reference point is set as a deteriorated distance; and
compensating for distortion of an image to be transferred from a pattern located at the deteriorated distance from the reference point of the mask design.

2. The method of claim 1,
wherein the plurality of chief ray angles are calculated using Equation 1:
$$\text{c6x\textasciicircum 6+c5x\textasciicircum 5+c4x\textasciicircum 4+c3x\textasciicircum c2x\textasciicircum 2+c1x,}$$
where x represents a distance between a point of interest of the plurality of points of interest and the reference point, c6 is -0.2995, c5 is 3.083, c4 is -10.67, c3 is 13.44, c2 is -8.388, and c1 is 25.12.

3. The method of claim 2, further comprising:
calculating a plurality of chief ray angle shrinkages by substituting the plurality of chief ray angles into Equation 2, respectively:
$$2.930 * tan \left(arcsin \left(sin \left(\text{CRA*pi/180}\right)\right.\right. / \left.\left.1.57755\right)\right) ,$$
where CRA represents one of the plurality of chief ray angles, and pi is a ratio of a circumference of a circle to a diameter of the circle,
wherein the circle is an imaginary circle with the reference point as a center of the circle.

4. The method of claim 1,
wherein the compensating for the distortion of the image to be transferred from the pattern located at the deteriorated distance includes:
performing optical proximity correction on the pattern located at the deteriorated distance from the reference point.

5. The method of claim 1,
wherein the reference point is disposed at a center of the mask design.

6. The method of claim 1,
wherein the reference point is disposed at an edge of the mask design.

7. The method of claim 1,
wherein the compensating of the pattern comprises correcting a critical dimension of the pattern.

8. An optical proximity correction method comprising designing a mask design, wherein the designing of the mask design comprises:
setting a reference point of the mask design;
setting a plurality of zones on the mask design, wherein the plurality of zones are concentric with reference to the reference point;
calculating a plurality of chief ray angles of a plurality of points of interest on the mask design, respectively, wherein each of the plurality of points of interest has a corresponding distance from the reference point;
finding, among the plurality of points of interest, a first point of interest having a maximum chief ray angle among the plurality of chief ray angles;
setting, among the plurality of zones, a first zone where the first point of interest having the maximum chief ray angle is located as a deteriorated zone; and
compensating for distortion of an image to be transferred from a pattern located in the deteriorated zone.

9. The method of claim 8,
wherein the plurality of chief ray angles are calculated using Equation 1:
$$\text{c6x\textasciicircum 6+c5x\textasciicircum 5+c4x\textasciicircum 4+c3x\textasciicircum 3+c2x\textasciicircum 2+c1x,}$$
where x represents a distance between a point of interest of the plurality of points of interest and the reference point, c6 is -0.2995, c5 is 3.083, c4 is -10.67, c3 is 13.44, c2 is -8.388, and c1 is 25.12.

10. The method of claim 9, further comprising:
calculating a plurality of chief ray angle shrinkages by substituting the plurality of chief ray angles into Equation 2, respectively:
$$\text{2} \text{.930*tan} \left(\text{arcsin} \left(\text{sin} \left(\text{CRA*pi/180}\right) \text{/} \left.\left.\text{1} \text{.57755}\right)\right)\right.\right. \text{,}$$
where CRA represents one of the plurality of chief ray angles, and pi is a ratio of a circumference of a circle to a diameter of the circle,
wherein the circle is an imaginary circle with the reference point as a center of the circle.

11. The method of claim 10,
wherein the compensating for the pattern located in the deteriorated zone includes:
performing optical proximity correction on the pattern located in the deteriorated zone.

12. The method of claim 8,
wherein the reference point is disposed at a center of the mask design.

13. The method of claim 8,
wherein the reference point is disposed at an edge of the mask design.

14. The method of claim 8,
wherein the compensating of the pattern comprises correcting a critical dimension of the pattern.

15. A photolithography method using a mask design on which an optical proximity correction method has been performed, the optical proximity correction method comprising designing the mask design, wherein the designing of the mask design comprises:
setting a reference point of the mask design;
calculating a plurality of chief ray angles of a plurality of points of interest on the mask design, respectively, wherein each of the plurality of points of interest has a corresponding distance from the reference point;
finding, among the plurality of points of interest, a first point of interest having a maximum chief ray angle among the plurality of chief ray angles, wherein a distance of the first point of interest from the reference point is set as a deteriorated distance; and
compensating for distortion of an image to be transferred from a pattern placed at the deteriorated distance from the reference point of the mask design.

16. The photolithography method of claim 15,
wherein the plurality of chief ray angles are calculated using Equation 1:
$$\text{c6x\textasciicircum 6+c5x\textasciicircum 5+c4x\textasciicircum 4+c3x\textasciicircum 3+c2x\textasciicircum 2+c1x,}$$
where x represents a distance between a point of interest of the plurality of points of interest and the reference point, c6 is -0.2995, c5 is 3.083, c4 is -10.67, c3 is 13.44, c2 is -8.388, and c1 is 25.12.

17. The photolithography method of claim 16, further comprising:
calculating a plurality of chief ray angle shrinkages by substituting the plurality of chief ray angles into Equation 2, respectively:
$$\text{2} \text{.930*tan} \left(\text{arcsin} \left(\text{sin} \left(\text{CRA*pi/180}\right) \left.\left.\text{/1} \text{.57755}\right)\right)\right.\right. \text{,}$$
where CRA represents one of the plurality of chief ray angles, and pi is a ratio of a circumference of a circle to a diameter of the circle,
wherein the circle is an imaginary circle with the reference point as a center of the circle.

18. The photolithography method of claim 15,
wherein the reference point is disposed at a center of the mask design.

19. The photolithography method of claim 15,
wherein the reference point is disposed at an edge of the mask design.

20. The photolithography method of claim 15,
wherein the compensating of the pattern comprises correcting a critical dimension of the pattern.
